(19) United States
(12) Patent Application Publication
(10) Pub. No.: US 2005/0287307 A1
(43) Pub. Date: Dec. 29, 2005

(54) Etch and deposition control for plasma implantation

(75) Inventors: Vikram Singh, North Andover, MA (US); Harold Persing, Rockport, MA (US); Timothy Miller, South Hamilton, MA (US); Atul Gupta, Beverly, MA (US); Ziwei Fang, Beverly, MA (US)

Correspondence Address: Mark A. Superko, Esq.;Varian Semiconductor Equipment Associates, Inc., 35 Dory Road, Gloucester, MA, 01930, US

(73) Assignee: Varian Semiconductor Equipment Associates, Inc., Gloucester, MA (US)

(21) Appl. No.: 10/874,944

(22) Filed: Jun. 23, 2004

(51) Int. Cl. C03C 15/00; C23C 14/00

(52) U.S. Cl. 427/523

(57) ABSTRACT

A method for ion implantation of a substrate includes forming a plasma from at least one implant material comprising at least one implant species, implanting the at least one implant species into a surface of the substrate, and directing at least one surface-modifying species at the surface to reduce a surface damage associated with the plasma. An apparatus for ion implantation is configured to implement this method.

### BACKGROUND OF INVENTION

1. Field of Invention

The invention is related to ion implantation for materials processing, and, in particular, to methods and apparatus for plasma implantation of dopants for fabrication of semiconductor-based devices.

2. Discussion of Related Art

The process of adding impurities to a semiconductor to control the semiconductor's electrical properties is known as “doping,” and suitable impurities are known as dopants. Some early doping techniques involved incorporation of dopant either during growth of a substrate, or diffusion of a dopant into a substrate from a gaseous or solid-phase material in contact with the substrate. Diffusion-based techniques involve elevated temperatures to obtain satisfactory dopant diffusion rates in the substrate.

Ion-implantation technology was developed in response to a demand for more precise control over spatial uniformity and concentration of dopants. A typical ion implanter ionizes a dopant in an ion source, the dopant ions are mass selected and accelerated to form an ion beam of prescribed energy, and the ion beam is directed at the surface of a wafer or other substrate. Energetic ions in the beam can penetrate the bulk of a semiconductor wafer, and become embedded in the crystalline lattice of the semiconductor material to form a region of desired conductivity. The wafer typically must be annealed after implantation to activate the implanted dopant, that is, to make the dopant electrically active.

Ion-implantation systems usually include an ion source that converts a gas or a solid material into a well-defined ion beam. The implanter mass analyzes the ion beam to eliminate undesired species, accelerates a desired species to a desired energy, and directs the beam at a target area of a substrate. The beam may be distributed over the target area by, for example, beam scanning, by target movement or by a combination of beam scanning and target movement. The implanter can thus provide precise control of dopant species, dopant ion implant energy, and dopant location. Unfortunately, however, a typical ion-beam implanter is a complex and costly machine, and can have a limited throughput.

In response to current trends in shallow-junction formation, technologists have recognized that a typical ion-beam implanter provides low beam currents at low-energy beam conditions. For example, at energies under 10 keV, as can be required for shallow junction formation, wafer throughput can suffer. In response to the need for implantation both at lower cost and with higher throughput at lower energies, plasma implantation techniques, such as plasma immersion ion implantation (PIII), have been proposed as a solution. In plasma implantation, a substrate and plasma typically share a process chamber. The substrate is exposed to the adjacent plasma, providing, for example, dopant implantation at a high dose rate at lower energies. Plasma implantation can also be implemented with relatively inexpensive equipment.

Plasma implantation can utilize a continuous or intermittent plasmas. In one type of plasma doping system, which utilizes an intermittent plasma, a semiconductor wafer is placed on a conductive platen, which functions as a cathode, located in a plasma doping chamber. An ionizable gas containing the desired dopant material is introduced into the chamber, and a voltage pulse is applied between the platen and an anode to form a glow-discharge plasma having a plasma sheath in the vicinity of the wafer. The applied voltage pulse causes ions in the plasma to cross the plasma sheath and to be implanted into the wafer. The depth of implantation is related to the voltage applied between the wafer and the anode. Very low implant energies can be achieved.

In PIII, which entails immersion in a plasma, a continuous or pulsed radio-frequency (RF) voltage typically is applied to produce a continuous or pulsed plasma. At intervals, a high-voltage pulse is applied to the platen to cause positive dopant ions in the plasma to be accelerated toward the wafer. A negative voltage pulse can be applied to extract positively charged dopant atoms from the plasma, and implant the ions into the wafer.

Unlike ion beam implantation, PIII and other plasma implantation techniques tend to implant other plasma ionized species in addition to the desired dopant species. Further, unwanted deposition and/or etch can occur as a function of the particular chemistry and operating conditions utilized for a particular implant process, due to exposure of a substrate to the plasma neutrals. For example, when using BF₃ as a dopant gas, plasma components related to fluorine can cause unwanted etching. Such effects can be reduced by proper selection of process parameters such as power level, gas pressure, and gas flow rate. The need to control process parameters, however, can limit satisfactory process windows.

### SUMMARY OF INVENTION

The invention arises in part from the realization that a surface subjected to plasma doping can be exposed to surface-modifying species that can reduce unwanted etching and/or reduce accumulation of deposits. The surface-modifying species can provide a protective surface barrier and/or etch deposits from a substrate surface. For example, a trace gas can be added to a dopant gas that is supplied to a plasma. The trace gas can be selected to provide a species that can passivate a surface to protect the surface from etching, and/or provide a species than can cause removal of surface deposits. Features of the invention can be applied, for example, to plasma doping tools, for example, tools that expose a substrate to a pulsed or continuous plasma. A passivating species can be, for example, one which bonds to a surface or forms a compound with surface atoms of the substrate. An etching species that removes surface deposits can be, for example, one which chemically etches and/or sputter etches unwanted deposits.

Accordingly, in a first aspect, the invention features a method for plasma implantation, such as plasma doping, of a substrate. The method includes forming a plasma from one or more implant materials, implanting one or more implant species into a surface of the substrate, and directing one or more surface-modifying species at the surface to reduce surface damage associated with the plasma. An implant material can provide at least one dopant species, and a surface-modifying material can provide one or more surface-modifying species. The substrate can be, for example, immersed in the plasma, or positioned near to the plasma, to provide implantation of species from the plasma, and the plasma can be formed from both the implant materials and the surface-modifying materials.

The surface damage can be associated with, for example, surface etching and/or surface deposits caused by the plasma. A surface-modifying species can provide passivation of a surface or can support etching of unwanted surface deposits. Passivation can be provided by, for example, formation of a surface barrier, which can include, for example, atoms or molecules bonded to the surface and/or a reacted surface layer. Etching can be associated with, for example, chemical and/or physical etching.

In a second aspect, the invention features an apparatus for ion implantation. The apparatus includes a vessel that contains a plasma and one or more substrates that can be immersed in the plasma. The apparatus also includes one or more implant material supplies, and one or more surface-modifying material supplies, which supply materials to the plasma in the vessel. The apparatus includes one or more material-supply control units that control a mixture of implant and surface-modifying materials supplied to the plasma.

### BRIEF DESCRIPTION OF DRAWINGS

The accompanying drawings, are not intended to be drawn to scale. In the drawings, each identical or nearly identical component that is illustrated in various figures is represented by a like numeral. For purposes of clarity, not every component may be labeled in every drawing. In the drawings:

FIG. 1 is a flowchart of an embodiment of a method for ion implantation of a substrate, according to principles of the invention.

FIG. 2 is a cross-sectional view of an embodiment of an apparatus for ion implantation, according to principles of the invention.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing”, “involving”, and variations thereof herein, is meant to encompass the items listed thereafter and equivalents thereof as well as additional items.

The word “plasma,” is used herein in a broad sense to refer to a gas-like phase that can include any or all of electrons, atomic or molecular ions, atomic or molecular radical species (i.e., activated neutrals), and neutral atoms and molecules. A plasma typically has a net charge that is approximately zero. A plasma may be formed from one or more materials by, for example, ionizing and/or dissociating events, which in turn may be stimulated by a power source with inductive and/or capacitive coupling.

The phrase “plasma implantation” is used herein to refer to implantation techniques that utilize implantation from a plasma without the mass selection features of a traditional beam implanter. A plasma implanter typically positions both a substrate and a plasma in the same chamber. The plasma can thus be near to the substrate or immerse the substrate. Typically, a variety of species types from the plasma will implant into the substrate.

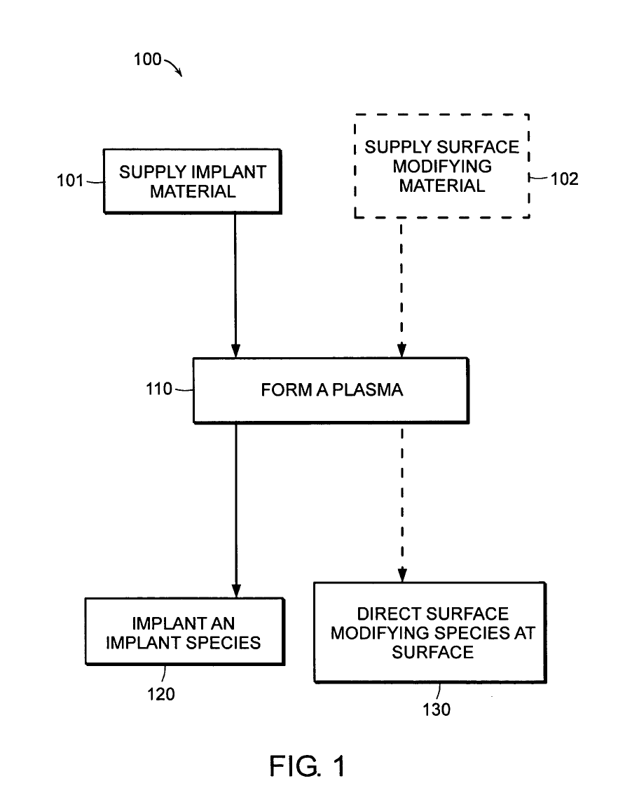

FIG. 1 is a flowchart of an embodiment of a method 100 for ion implantation of a substrate, according to principles of the invention. The method 100 includes forming a plasma (Step 110) from at least one implant material, implanting (Step 120) at least one implant species from the plasma, and directing at least one surface-modifying species at the surface (Step 130) to reduce surface damage associated with the plasma.

The at least one implant material can be, for example, any material that provides one or more dopant species. The one or more dopant species can then be implanted (Step 120) into the substrate, for example, a silicon-based substrate. Some suitable dopant materials include, for example, AsH₃, PH₃, BF₃, AsF₅, PF₃, B₅H₉, and B₂H₆.

The following description of the behavior of the implant material BF₃ illustrates principles of the invention. It will be understood by one having ordinary skill in the ion implantation arts that the described examples are non-limiting, and that principles of the invention may be applied to a broad range of implant materials and implant species.

A plasma formed from BF₃ can include, for example, radicals of BF₃, BF₂, BF, B and F, positive ions of BF₂, BF, B and F, and electrons, in addition to unexcited BF₃ and other molecules and atoms. Such a plasma typically includes, as a majority component, gas and etch-product molecules, a lesser component of radicals, and a much smaller component of ions and electrons. B ions, as well as other ions in the plasma, can be implanted (Step 120) via, for example, plasma immersion implantation or other plasma implantation approach.

For plasma implantation, the plasma can both serve as a source of a desired B implant species, and can also lead to typical fluorine-based reactive ion etching. In general, reactive radicals, such as radical F atoms, can contribute to etching of a substrate. Other radicals, such as those of BF₂, BF, B, and clusters of radicals, can contribute to deposition on the surface of a substrate. Ions, such as BF₃, BF₂, BF, B and F, can contribute to ion implantation into the substrate, and can contribute to sputter etching of the substrate.

Chemical etching can arise from, for example, radical F atoms reacting with silicon in a substrate or B-containing components deposited on the surface to form, respectively, SiF₄ or BF₃. These reaction products can be volatile and can thus escape from the surface of a substrate. Further, ions from the plasma can enhance etching due to, for example, facilitation of adsorption of F radicals and desorption of reaction byproducts, such as the above-mentioned SiF₄ or BF₃.

Further, ion bombardment of nonvolatile materials on a surface can expose the surface to fresh chemical attack. When deposition of nonvolatile materials occurs, such as deposition arising from radicals, such as those of BF₂, BF, B, and clusters of radicals, the deposition byproducts can accumulate on a substrate surface.

To mitigate etch and/or deposition effects associated with B implantation, and with implantation of other implant species, one or more surface-modifying species are directed at the substrate (Step 130) to passivate the surface against etch attack and/or to remove deposition material. A surface-modifying species can be derived from a surface-modifying material. Moreover, the plasma can be formed (Step 110) from both one or more implant materials (Step 101) and from one or more surface-modifying materials (Step 102) to provide the implant species and surface-modifying species from the plasma. For example, a gaseous surface-modifying material can be added to a gaseous implant material prior to supplying the mixed gases to a plasma utilized for plasma implantation (Step 120). One or more surface-modifying species can then be directed at the substrate (Step 130) from the plasma to reduce etch or deposition damage of the surface that would otherwise arise from implantation (Step 120) via plasma implantation.

For example, a surface-modifying material can be a surface passivating material that provides a surface passivating species that can reduce etch damage. A surface passivating material can be, for example, N₂, O₂, SiH₄, SiF₄, Tetraethoxysilane, CₓH_{y} or CₓH_{y}O_{z}. These materials can provide surface passivating species, which can be directed at a surface from a plasma, such as B, C, Si, N, and O. The surface passivating species may attach to, or react with, the substrate to form an etch barrier. The etch barrier can impede attack of the substrate surface by blocking etch precursors from attacking the surface and removing (etching) surface material.

A barrier may be formed by species that attach to the substrate surface, for example, B, Si, and/or C attaching to a silicon substrate surface. A barrier may be formed by a species that reacts with the surface, for example, O forming SiO₂ and/or N forming Si₃N₄ on the surface of a silicon substrate. The etch barrier can protect the surface from, for example, radical F produced by a BF₃-based plasma.

As mentioned above, a surface-modifying material can be an etching material that provides an etching species that can etch plasma byproducts that have deposited on a substrate surface. An etching material can be, for example, a chemical-etching material and/or a sputter-etching material. For example, a chemical etching material can be H₂, NH₃, NF₃, F₂, and CₓFₓH_{z}. These materials can provide chemical-etching species, which can be directed at a surface from a plasma, such as H, F, and Cl. These reactive species can combine with deposited materials to assist removal of the materials by, for example, forming volatile compounds with the deposited materials. For example, H, F, and Cl can chemically attack deposits derived from radicals, or clusters, of radicals of BF₂, BF, B.

A sputter etching material can be, for example, a noble gas, for example, He, Ne, Ar or Xe. Argon ions, for example, can be directed at a sample surface, from an immersion or other adjacent plasma, to sputter etch deposits on the sample surface.

In some embodiments of the invention, gas is supplied to a plasma at a pressure in a range of, for example, about 1 mTorr to about 50 mTorr. An implant gaseous material can be supplied at a flow rate in a range of, for example, about 5 standard cubic centimeters per minute (sccm) to about 5000 sccm. A surface modifying gaseous material can be supplied at a flow rate in a range of, for example, about 0.1 sccm to about 500 sccm. The plasma formed from the gases can be operated at a power in a range of, for example, about 100 watts to about 5000 watts.

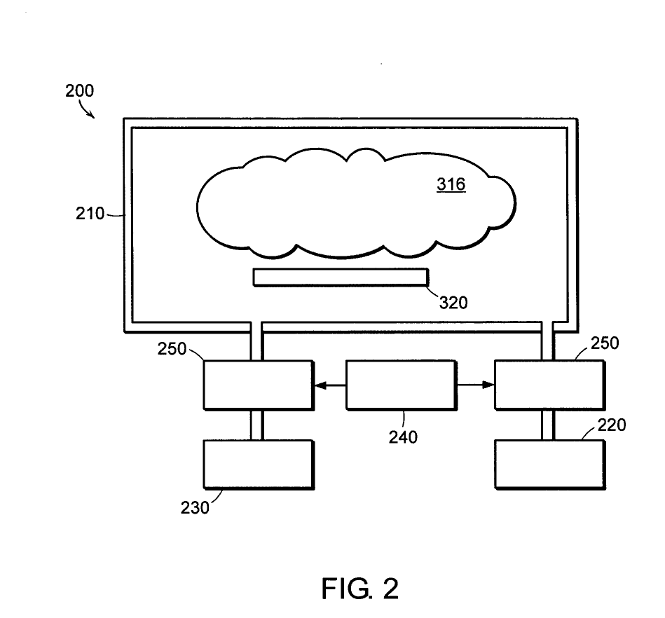

Now referring to FIG. 2, some embodiments of the invention entail apparatus for plasma implantation, such as plasma doping. FIG. 2 is an embodiment of an apparatus 200 that can be used, for example, to perform the above-described method 100. The apparatus 200 includes a vessel 210 that can contain a plasma 310 and one or more substrates 320, which can be exposed to the plasma. The apparatus 200 also includes one or more implant material supplies 220, one or more surface-modifying material supplies 230, flow controllers 250, and one or more material-supply control units 240.

The material supplies 220, 230 supply materials to the vessel 210 for formation and maintenance of a plasma. The flow controllers 250 mediate the flow of materials from the supplies 220, 230 to control, for example, the pressure of gaseous material delivered to the vessel 210. The material-supply control unit 240 is configured to control, for example, a mixture of implant and surface-modifying materials supplied to the vessel 210 by communicating with the flow controllers 250. Thus, according to principles of the invention described above with respect to the method 100, the apparatus 200 can be used, for example, to plasma dope a substrate while reducing substrate damage due to unwanted deposition or etching associated with the plasma.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

1. A method for ion implantation of a substrate, the method comprising:
forming a plasma from at least one implant material comprising at least one implant species;
implanting, by plasma implantation, the at least one implant species into a surface of the substrate; and
directing at least one surface-modifying species at the surface to reduce a surface damage associated with the plasma.

2. The method of claim 1, wherein forming comprises forming the plasma from the at least one implant material and at least one surface-modifying material comprising the at least one surface-modifying species.

3. The method of claim 2, wherein the at least one implant material and the at least one surface-modifying material are gases, and further comprising mixing a trace of the at least one surface-modifying material with the at least one implant material prior to forming the plasma.

4. The method of claim 1, wherein the surface damage comprises an etching of the surface.

5. The method of claim 4, wherein the at least one surface-modifying species comprises at least one surface passivating species, and directing comprises forming an etch barrier comprising the at least one surface passivating species on the surface to reduce the etching of the surface.

6. The method of claim 5, wherein the at least one passivating species comprises at least one element selected from the group consisting of B, C, Si, N, and O.

7. The method of claim 5, further comprising deriving the at least one surface passivating species from at least one material selected from the group consisting of N₂, O₂, SiH₄, SiF₄, Tetraethoxysilane, CₓH_{y} and CₓH_{y}O_{z}.

8. The method of claim 1, wherein the surface damage comprises a deposition on the surface.

9. The method of claim 8, wherein the at least one surface-modifying species comprises at least one etching species, and directing comprises causing the at least one etching species to etch at least a portion of the surface deposit.

10. The method of claim 9, wherein the at least one etching species is associated with at least one chemical-etching material.

11. The method of claim 10, wherein the at least one chemical-etching material is selected from the group consisting of H₂, NH₃, NF₃, F₂, and CₓFₓH_{z}.

12. The method of claim 9, wherein the at least one etching species is associated with at least one sputtering material.

13. The method of claim 12, wherein the at least one sputtering material is selected from the group consisting of noble gases.

14. The method of claim 8, wherein the deposition comprises at least one byproduct associated with forming the plasma and implanting the at least one implant species.

15. The method of claim 1, wherein implanting and directing occur at least partially at the same time.

16. The method of claim 1, wherein the at least one implant material comprises at least one dopant species.

17. The method of claim 16, wherein the dopant species is selected from the group consisting of B, P, As, and Sb.

18. The method of claim 17, wherein the at least one implant material comprises at least one material selected from the group consisting of AsH₃, PH₃, BF₃, AsF₅, PF₃, B₅H₉, and B₂H₆.

19. The method of claim 1, wherein the plasma is of a type selected from a group consisting of a glow plasma and a RF plasma.
